(19) United States
(12) Patent Application Publication
(10) Pub. No.: US 2026/0141973 A1
(43) Pub. Date: May 21, 2026

(54) MEMORY SYSTEM FOR PERFORMING POST PACKAGE REPAIR AND AN OPERATION METHOD THEREOF

(71) Applicant: SK hynix Inc., Gyeonggi-do (KR)

(72) Inventor: Du Hyun KIM, Gyeonggi-do (KR)

(21) Appl. No.: 19/087,595

(22) Filed: Mar. 24, 2025

(30) Foreign Application Priority Data
Nov. 19, 2024 (KR) 10-2024-0164837

(51) Int. Cl. G11C 29/44; G11C 29/12

(52) U.S. Cl. CPC G11C 29/4401; G11C 29/1201

(57) ABSTRACT

A memory system includes at least one memory device and a controller. The controller includes an input path for transferring a data input/output (I/O) request input from an external device to the at least one memory device and an output path for transferring a response corresponding to the data I/O request. The controller is configured to selectively couple the output path to the input path for a post package repair (PPR) operation.

### CROSS-REFERENCE TO RELATED APPLICATIONS

This patent application claims the benefit of priority under 35 U.S.C. § 119(a) to Korean Patent Application No. 10-2024-0164837, filed on Nov. 19, 2024, the entire disclosure of which is incorporated herein by reference.

### TECHNICAL FIELD

Various embodiments of the present disclosure described herein relate to a memory system, and more particularly, to a memory system providing a post package repair (PPR) and an operation method of the memory system.

### BACKGROUND

A computing system is increasing an amount of computation in response to user needs. As the amount of computation increases, an amount of data generated or stored is also increasing. A memory system in the computing system performs an operation of inputting and outputting data in response to a request from an external device such as a host. The memory system can include at least one memory device. The memory device can include at least one of a volatile memory cell and a non-volatile memory cell, for storing data.

The memory device can include a plurality of memory cells arranged in a matrix form of a plurality of rows and a plurality of columns. The memory device includes a redundant memory cell for replacing a defective memory cell among the plurality of memory cells and performs a repair operation of replacing a memory row to which the defective memory cell is connected with a redundant row. A Post Package Repair (PPR) refers to a repair operation performed after the memory device is packaged.

### BRIEF DESCRIPTION OF THE DRAWINGS

The description herein makes reference to the accompanying drawings wherein like reference numerals refer to like parts throughout the figures.

FIG. 1 illustrates a first data processing apparatus according to an embodiment of the present disclosure.

FIG. 2 illustrates a memory device according to an embodiment of the present disclosure.

FIG. 3 illustrates a first memory controller according to an embodiment of the present disclosure.

FIG. 4 illustrates a data input/output operation performed in a memory controller according to an embodiment of the present disclosure.

FIG. 5 illustrates a configuration of a volatile memory device included in a memory controller according to an embodiment of the present disclosure.

FIG. 6 illustrates a second memory controller according to an embodiment of the present disclosure.

FIG. 7 illustrates a post package repair (PPR) operation of the memory controller described in FIG. 6.

FIG. 8 illustrates a second data processing apparatus according to an embodiment of the present disclosure.

FIG. 9 illustrates a third data processing apparatus according to an embodiment of the present disclosure.

### DETAILED DESCRIPTION

Various embodiments of the present disclosure are described below with reference to the accompanying drawings. In this disclosure, elements and features may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components e.g., an interface unit, circuitry, etc.

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational, e.g., is not turned on nor activated. Examples of block/unit/circuit/component used with the “configured to” language include hardware, circuits, memory storing program instructions executable to implement the operation, etc. Additionally, “configured to” can include a generic structure, e.g., generic circuitry, that is manipulated by software and/or firmware, e.g., an FPGA or a general-purpose processor executing software to operate in a manner that is capable of performing the task(s) at issue. “Configured to” may also include adapting a manufacturing process, e.g., a semiconductor fabrication facility, to fabricate devices, e.g., integrated circuits that are adapted to implement or perform one or more tasks.

As used in this disclosure, the term ‘machine,’ ‘circuitry’ or ‘logic’ refers to all of the following: (a) hardware-only circuit implementations such as implementations in only analog and/or digital circuitry and (b) combinations of circuits and software and/or firmware, such as (as applicable): (i) to a combination of processor(s) or (ii) to portions of processor(s)/software including digital signal processor(s), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘machine,’ ‘circuitry’ or ‘logic’ applies to all uses of this term in this application, including in any claims. As a further example, as used in this application, the term ‘machine,’ ‘circuitry’ or ‘logic’ also covers an implementation of merely a processor or multiple processors or a portion of a processor and its (or their) accompanying software and/or firmware. The term ‘machine,’ ‘circuitry’ or ‘logic’ also covers, for example, and if applicable to a particular claim element, an integrated circuit for a storage device.

As used herein, the terms ‘first,’ ‘second,’ ‘third,’ and so on are used as labels for nouns that they precede, and do not imply any type of ordering, e.g., spatial, temporal, logical, etc. The terms ‘first’ and ‘second’ do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term ‘based on’ is used to describe one or more factors that affect a determination. This term does not foreclose additional factors that may affect a determination. That is, a determination may be solely based on those factors or based, at least in part, on those factors. Consider the phrase “determine A based on B.” While in this case, B is a factor that affects the determination of A, such a phrase does not foreclose the determination of A from also being based on C. In other instances, A may be determined based solely on B.

Embodiments of the present disclosure can provide an apparatus and a method which can use an input/output (I/O) buffer established for a data input/output operation to perform a post package repair (PPR) operation for a memory device, without establishing or setting an additional buffer.

Further, an embodiment of the present disclosure can provide an apparatus and a method that can allow the memory system to perform a post package repair (PPR) operation, based on an operating environment and an operating state, without preoccupying additional resources for the PPR operation, to improve and enhance data input/output (I/O) performance and operational safety of the memory system by allowing more internal resources to be allocated for data I/O operations.

In an embodiment of the present disclosure, a memory system can include at least one memory device; and a controller comprising an input path for transferring a data input/output (I/O) request input from an external device to the at least one memory device and an output path for transferring a response corresponding to the data I/O request. The controller can be configured to selectively couple the output path to the input path for a post package repair (PPR) operation.

The controller can further include a request buffer included in the input path and configured to store the data I/O request; a response buffer included in the output path and configured to store the response; a first multiplexer configured to transfer an output of the response buffer to the external device or activate a loopback for routing the output of the response buffer to the request buffer; and a second multiplexer configured to transfer one of the data I/O request and an output of the first multiplexer to the request buffer.

The controller can include a layered structure including a first interface layer configured to perform data communication with the external device; a second interface layer configured to perform data communication with the at least one memory device; and a control logic layer arranged between the first interface layer and the second interface layer and configured to control or manage operations to be performed through the first interface layer and the second interface layer.

The control logic layer can include a data input/output circuitry configured to handle or process the data input/output request; a post package repair control circuitry configured to perform the PPR operation; and a memory management circuitry configured to check, track, or manage an operation status of the memory system.

The post package repair control circuitry can be configured to determine whether to perform the post package repair operation in an idle state; control the first multiplexer to loop back the output of the response buffer to the second multiplexer and control the second multiplexer to transfer the output of the first multiplexer to the request buffer to enable the PPR operation.

The memory management circuitry can be configured to check whether the memory system is in an idle state to transfer a status of the memory system to the post package repair control circuitry; and transfer, for the PPR operation, a read request regarding data stored at a first location, which needs to be repaired, to the at least one memory device.

The controller can be configured to store the data in a second location, which is different from the first location, in the at least one memory device; and replace an address of the first location with an address of the second location.

The controller can further include a volatile memory configured to store input/output results of tasks processed or transferred in the first interface layer, the second interface layer, and the control layer. Each of the request buffer and the response buffer can be established or set in the volatile memory.

The controller can further include a third multiplexer configured to transfer one of the output of the request buffer and a meaningless signal to the at least one memory device.

The controller can be configured to perform an error correction operation on data output from the at least one memory device based on a read request generated by, or transmitted from, a memory management circuitry. The controller can be configured without a dedicated buffer used for the PPR operation only.

In an embodiment, a controller can include at least one processor and at least one memory. The controller can be configured to perform a post package repair (PPR) operation for at least one memory device and activate a loopback for coupling an output path to an input path during the PPR operation. The input path can be configured to transfer a data input/output (I/O) request input from an external device to the at least one memory device and the output path is configured to transfer a response corresponding to the data I/O request to the external device.

The controller can further include a request buffer located on the input path and configured to store the data I/O request; a response buffer located on the output path and configured to store the response; a first multiplexer configured to transfer an output of the response buffer to the external device or activate a loopback for routing the output of the response buffer to the request buffer; and a second multiplexer configured to transfer one of the data I/O request and an output of the first multiplexer to the request buffer.

The controller can further include a layered structure including a first interface layer configured to perform data communication with the external device; a second interface layer configured to perform data communication with the at least one memory device; and a control logic layer arranged between the first interface layer and the second interface layer and configured to control or manage operations to be performed through the first interface layer and the second interface layer.

The control layer can include a data input/output circuitry configured to handle or process the data input/output request; a post package repair control circuitry configured to perform the PPR operation; and a memory management circuitry configured to check, track, or manage operation statuses of the at least one memory and the at least one processor.

The post package repair control circuitry can be configured to determine whether to perform the post package repair operation in an idle state; and control the first multiplexer to loop back the output of the response buffer to the second multiplexer control the second multiplexer to transfer the output of the first multiplexer to the request buffer to enable the PPR operation.

The memory management circuitry can be configured to check whether the data input/output request is input from the external device to transfer a checked status to the post package repair control circuitry; and transfer, for the PPR operation, a read request regarding data stored at a first location, which needs to be repaired, to the at least one memory device.

The controller can further include a volatile memory configured to store input/output results of tasks processed or transferred in the first interface layer, the second interface layer, and the control layer. Each of the request buffer and the response buffer can be established or set in the volatile memory.

The controller can further include a third multiplexer configured to transfer one of the output of the request buffer and a meaningless signal to the at least one memory device.

In another embodiment, a method for operating a memory system can include activating a loopback for coupling an output path to an input path during a post package repair (PPR) operation for at least one memory device included in the memory system. The input path can be configured to transfer a data input/output (I/O) request input from an external device to the at least one memory device. The output path can be configured to transfer a response corresponding to the data I/O request to the external device.

The method can further include checking whether the at least one memory device is in an idle state; performing a read operation regarding data stored at a first location of the at least one memory device, the first location subject to the PPR operation; storing the data returned through the output path and the input path in a second location of the at least one memory device; and replacing an address of the first location with an address of the second location.

These and other features and advantages of the invention will become apparent from the detailed description and the accompanying drawings of embodiments of the present disclosure. Embodiments will now be described with reference to the accompanying drawings, wherein like numbers reference like elements.

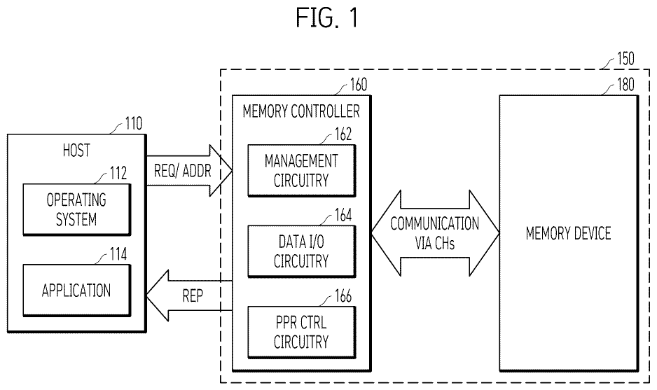

FIG. 1 illustrates a first data processing apparatus according to an embodiment of the present disclosure.

Referring to FIG. 1, the first data processing apparatus can include a host 110 and a memory system 150.

The memory system 150 can perform a write operation or a read operation according to a data input/output (I/O) request input from the host 110. The memory system 150 can include a memory controller 160 and a memory device 180 which can perform data communication with each other through a data path or channels (CHs). According to an embodiment, the memory device 180 may include at least one of a plurality of volatile memory cells and a plurality of nonvolatile memory cells.

The host 110 can include electronic devices such as a computer, a laptop computer, a smart phone, a smart pad, a smart TV, a netbook, etc. The host 110 can access the memory system 150 in conjunction with operations of an application 114 and an operating system 112.

The host 110 can transmit a request REQ and an address ADDR to the memory system 150. The memory system 150 can transmit a response REP corresponding to the request REQ to the host 110. The request REQ that the host 110 transfers to the memory system 150 can include a data input/output request, such as a read request for reading data stored in the memory device 180, a write request for storing data in the memory device 180, etc. Further, according to an embodiment, the host 110 can transfer to the memory system 150 a sort of request or command that can help maintain performance of the memory system 150 or manage, interrupt, or control internal operations of the memory system 150.

The memory controller 160 can include a memory management circuitry 162, a data input/output circuitry 164, and a post package repair control circuitry 166. The configuration of the memory controller 160 can vary based on requested or designed performance of the memory system 150. According to an embodiment, each of the memory management circuitry 162, the data input/output circuitry 164, and the post package repair control circuitry 166 within the memory controller 160 can be configured as independent modules. Further, according to an embodiment, each of the memory management circuitry 162, the data input/output circuitry 164, and the post package repair control circuitry 166 within the memory controller 160 can be implemented as a functional unit or block capable of performing a designed operation through internal resources such as at least one processor, core, or logic and at least one memory or buffer capable of operatively engaging with the at least one processor, core, or logic.

The data input/output circuitry 164 can process or handle a data input/output request transferred from the host 110. For example, based on a read request and an address input from the host 110, the data input/output circuitry 164 can output data stored in the memory device 180 to the host 110. In addition, in response to a write request and address input from the host 110, the data input/output circuitry 164 can store data in a location corresponding to the address (e.g., memory cells accessed by row/column addresses). Because the memory system 150 is a type of apparatus for storing and outputting data, operations of the data input/output circuitry 164 can have the greatest influence on the performance of the memory system 150. The data input/output circuitry 164 can preferentially use internal resources included in the memory system 150 for efficiently and quickly processing or handling data input/output requests input from the host 110.

The post package repair control circuitry 166 can perform or control a post package repair (PPR) operation. The post package repair (PPR) operation can include a memory self-healing process that replaces access to a defective memory cell, row, or column with access to a spare memory cell, row, or column in the memory device 180. The post package repair (PPR) could be broadly divided into a soft post package repair (sPPR) and a hard post package repair (hPPR). The soft post package repair (sPPR) can repair a defective cell, row, or column for a current boot cycle. Therefore, when power to the data processing apparatus or the memory system 150 is removed or the data processing apparatus or the memory system 150 is rebooted or reset, the memory system 150 could return to an original state. On the other hand, the hard post package repair (hPPR) can permanently repair a defective cell, row, or column.

According to an embodiment, the memory system 150 can perform the PPR operation based on the request REQ from the host 110, or the memory system 150 can perform the PPR operation without any request REQ input from the host 110. For example, the hard post package repair (hPPR) operation can be performed based on the request REQ input from the host 110. The host 110 can transmit the request REQ along with the address ADDR of a defective cell, row, or column in the memory device 180 to the memory system 150. In this case, as the response REP to the request REQ from the host 110, the memory system 150 can transfer to the host 110 an address of a cell, row, or column that can replace the address of the defective cell, row, or column after the hard post package repair (hPPR) operation. Afterwards, the host 110 can use the address of the replaced cell, row, or column, not the address of the defective cell, row, or column. Through this procedure, the operational stability of the data processing apparatus can be improved or enhanced.

According to an embodiment, the memory system 150 can perform the soft post package repair (sPPR) operation based on the request REQ of the host 110. In addition, according to an embodiment, the memory system 150 can perform the hard post package repair (hPPR) operation or the soft post package repair (sPPR) operation without the request REQ of the host 110. In addition, in a case when the request REQ is input from the host 110, the memory system 150 can check whether there is a data input/output request transferred from the host 110 to perform the hard post package repair (hPPR) operation or the soft post package repair (sPPR) operation. The memory system 150 can perform the PPR operation on the memory device 180 that is in an idle state.

The memory management circuitry 162 can check, track, or manage operation statuses of the memory device 180 and the memory controller 160 in the memory system 150. In order to improve the data input/output performance of the memory system 150, the memory controller 160 and the memory device 180 can include various devices or components for improving the data input/output performance. To systematically link these various devices or components, the memory management circuitry 162 can check an operation status of each device or component and check whether a plurality of detailed tasks or jobs are sequentially performed. The memory management circuitry 162 can be used to avoid malfunctions in the memory system 150 and to improve the overall performance of the memory system 150.

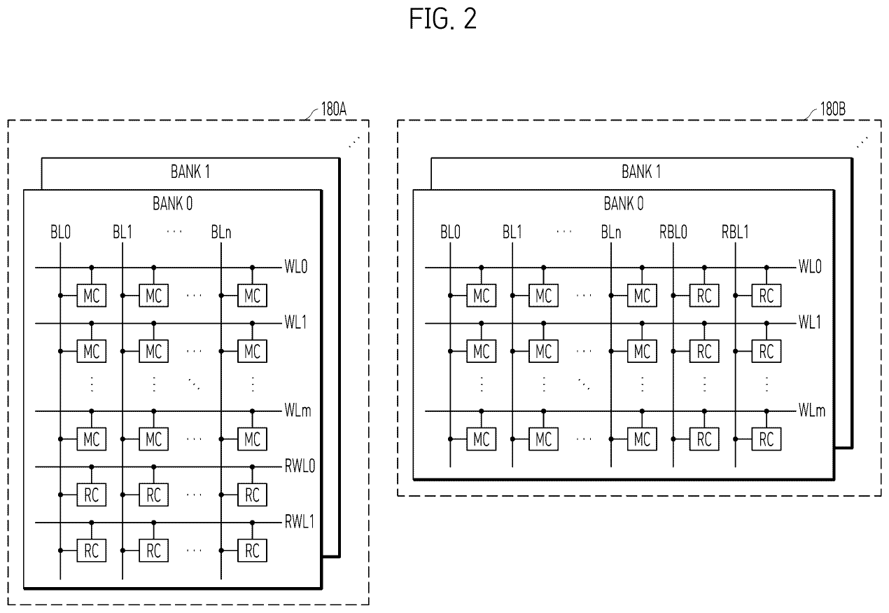

FIG. 2 illustrates a memory device according to an embodiment of the present disclosure. Specifically, FIG. 2 shows plural examples of the memory device 180 described in FIG. 1.

Referring to FIGS. 1 and 2, the memory device 180 can include a plurality of memory chips, a plurality of memory dies, or a plurality of memory banks. For example, the plurality of memory banks in the memory device 180 can include a structure or a component supporting the post package repair (PPR) operation.

A first memory device 180A can include redundancy cells RC for supporting the post package repair (PPR) operation. The redundancy cells RC can be accessed through redundancy word lines RWL0, RWL1. For data input/output operations, the plurality of memory cells MC included in a first bank BANK0 in the first memory device 180A can be accessed through word lines WL0 to WLm and bit lines BL0 to BLn. If a defect occurs in at least some of the memory cells MC accessed through the word lines WL0 to WLm, the redundancy cells RC can be used to replace the defective memory cell through the post package repair (PPR) operation. For example, if a defect occurs in the memory cell MC coupled to the first word line WL0, the first word line WL0 can be replaced with the first redundancy word line RWL0.

A second memory device 180B can include the redundancy cells RC to support the post package repair (PPR) operation. The redundancy cells RC can be accessed through redundancy bit lines RBL0, RBL1. For data input/output operations, a plurality of memory cells MC included in the first bank BANK0 in the first memory device 180A can be accessed through the word lines WL0 to WLm and the bit lines BL0 to BLn. If a defect occurs in at least some of the memory cells MC accessed through the bit lines BL0 to BLn, the redundancy cells RC can be used to replace the defective memory cell through the post package repair (PPR) operation. For example, if a defect occurs in the memory cell MC connected to the first bit line BL0, the first bit line BL0 can be replaced with the first redundancy bit line RBL0.

According to an embodiment, the number of redundancy cells RC included in the memory device 180 and positions where the redundancy cells RC are arranged could be changed. Based on the structure of the redundancy cells RC, the post package repair (PPR) operation can include tasks or jobs for a row-by-row or column-by-column repair operation in each memory bank or each memory die.

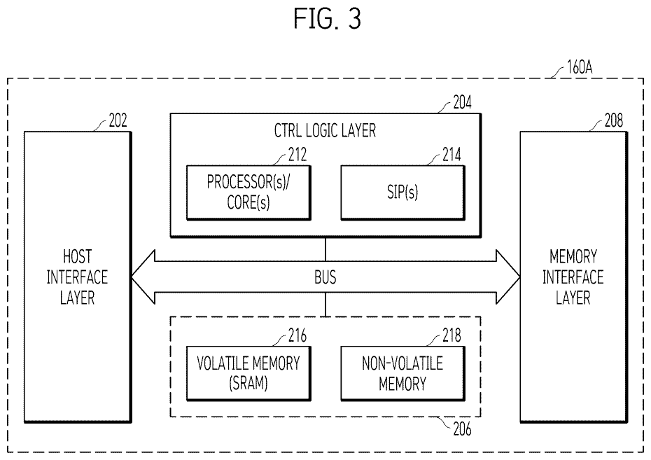

FIG. 3 illustrates a first memory controller 160A according to an embodiment of the present disclosure. Specifically, FIG. 3 illustrates a first example corresponding to the memory controller 160 described in FIG. 1.

Referring to FIG. 3, the first memory controller 160A can have a layered structure. Here, the layered structure is a type of system structure in which various services, operations, or tasks of the memory controller 160A can be allocated to plural layers. Each layer can have at least one component for performing a specific or designed service, operation, or task which is allocated thereto.

The first memory controller 160A can include a host interface layer 202, a control logic layer 204, and a memory interface layer 208. The host interface layer 202, the control logic layer 204, and the memory interface layer 208 can interact with each other through a means for temporarily storing and transferring data, tasks, or results, such as a buffer, a queue, etc.

According to an embodiment, the control logic layer 204 can include at least one processor or core 212 and at least one semiconductor intellectual property core (SIP) core 214. Here, the semiconductor intellectual property core is also referred to as an IP core or an IP block. The semiconductor intellectual property core can refer to a logic, cell, integrated circuit, or a layout design implemented based at least on a specific intellectual property (IP). For example, the semiconductor intellectual property core 214 can include a logic, cell, circuit layout, part or the entirety of a (micro)processor.

The control logic layer 204 can be divided into plural components or units of specific or designed services, operations, or tasks to be assigned or allocated thereto. The divided blocks can be performed through the at least one processor or core 212 or the at least one semiconductor intellectual property core 214. The at least one processor or core 212 or the at least one semiconductor intellectual property core 214 can be coupled to internal resources 206 through a system bus (BUS). According to an embodiment, the memory management circuitry 162, the data input/output circuitry 164, and the post package repair control circuitry 166 described in FIG. 1 can be components included in the control logic layer 204.

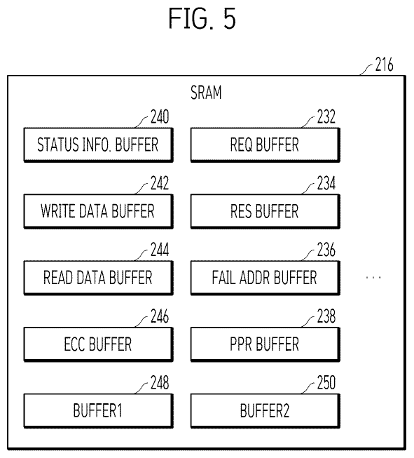

According to an embodiment, the internal resource 206 can include at least one of a volatile memory 216 and a non-volatile memory 218. The non-volatile memory 218 can store firmware, etc. which is designed and configured to carry out the operation of the first memory controller 160A. In addition, among the internal resources 206, the volatile memory 216 can serve as buffers, queues, etc. used in, or engaged with, the host interface layer 202, the control logic layer 204, and the memory interface layer 208. For example, the volatile memory 216 may include an SRAM, and the non-volatile memory 218 may include a NAND flash memory. A description of the internal resource 206 will be described later with reference to FIG. 5.

The host interface layer 202 can support data communication between the first memory controller 160A and an external device. For example, the host interface layer 202 can receive the request REQ or the address ADDR transferred by the host 110 described in FIG. 1 and transmit the request REQ or the address ADDR to the control logic layer 204. In addition, the host interface layer 202 can transmit the response REP prepared by the control logic layer 204 to the host 110 which is the external device.

The memory interface layer 208 can perform operations for supporting data communication between the first memory controller 160A and the memory device 180. For example, the memory interface layer 208 can transmit a data input/output request or a post package repair (PPR) request to the memory device 180. In addition, the memory interface layer 208 can receive data from the memory device 180 or receive a completion signal corresponding to a request that has already been transmitted to the memory device 180. The control logic layer 204 can generate or configure the response REP regarding a currently performing or performed task or request. Further, the control logic layer 204 can terminate operations corresponding to the request based on data, completion signals, etc. transmitted through the memory interface layer 208.

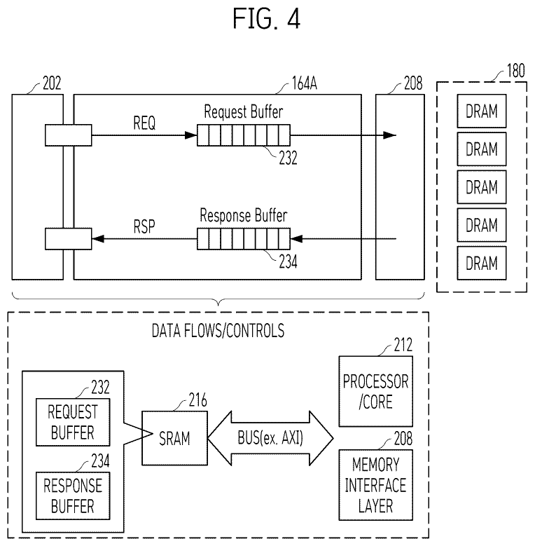

FIG. 4 illustrates a data input/output operation performed in a memory controller according to an embodiment of the present disclosure.

Referring to FIG. 4, the memory device 180 can include a plurality of DRAMs. The memory interface layer 208 can transmit requests, write data, etc. to the plurality of DRAMs in the memory device 180, or receive read data, etc. from the plurality of DRAMs in the memory device 180.

When performing a data input/output operation in a memory system, an input path and an output path can be formed in the host interface layer 202, a data input/output circuit 164A, and the memory interface layer 208. The input path refers to a processing line or path for transferring the request REQ transmitted from the host interface layer 202 to the data input/output circuit 164A to the memory interface layer 208. The process or operation of transferring the request REQ from the host interface layer 202 to the memory interface layer 208 can be complicated depending on the performance of the memory system. For example, the data input/output circuit 164A can verify the validity of the request REQ or security-related information associated with the request REQ. In addition, the data input/output circuit 164A can schedule multiple data input/output operations, such as reading and writing, performed in the plurality of DRAMs, and can detect and resolve various types of hazards.

The data input/output circuit 164A can be configured to detect and resolve various types of hazards (e.g., data hazards, control hazards, structural hazards, etc.) that might occur during a pipeline process that improves a processing speed of the memory system by dividing and allocating tasks or operations corresponding to a request or command into multiple stages and processing the tasks or operations simultaneously within the memory controller. One of representative components included in this input path can be a request buffer 232. The request buffer 232 can temporarily store multiple data input/output requests that have been or are scheduled to be transmitted to the plurality of DRAMs in the memory device 180.

Moreover, the output path refers to a processing line or path for transferring information from the memory interface layer 208 to the host interface layer 202. For example, the read request REQ and the address can be transmitted to a DRAM in the memory device 180 through the input path. The memory device 180 can transmit read data stored in a memory cell corresponding to the address transmitted along with the read request to the memory interface layer 208. The memory interface layer 208 can transmit the data transmitted from the memory device 180 to the data input/output circuit 164A.

According to an embodiment, the memory interface layer 208 can check and correct errors in the data output from the memory device 180 based on an error correction code (ECC), parity, etc. The data input/output circuit 164A can generate a response based on the read data output from the memory interface layer 208 and the read request stored in the request buffer 232. This response can be temporarily stored in a response buffer 234. The response stored in the response buffer 234 can be transferred to the host interface layer 202. According to an embodiment, the output path can have different components depending on the operational performance of the memory system. One of representative components included in the output path can be the response buffer 234.

According to an embodiment, the memory controller may be implemented as a system-on-chip (SoC). As described in FIG. 3, the memory controller can include at least one of the at least one processor or core 212 and the at least one semiconductor intellectual property core 214 and at least one of the volatile memory 216 and the non-volatile memory 218. The request buffer 232 and the response buffer 234 can be set in the volatile memory 216. If the aforementioned input path and output path refer to sequential processes in which services, operations, and tasks are performed, the actual data or signal flow and control within the memory controller of the system-on-chip (SoC) can include interactions or exchanges of data and signals between internal components (e.g., the volatile memory 216, the processor or core 212, the memory interface layer 208, etc.) connected by a bus or interface (e.g., AXI interface, etc.).

It might be difficult to change or modify a memory controller implemented as the system-on-chip (SoC) after manufacturing the memory controller. Therefore, the memory controller can improve data input/output performance as the use of limited internal resources (e.g., a memory, a processor, etc.) is efficient. In addition, when the limited internal resources are efficiently allocated to each layer or each functional configuration block or unit included in the memory controller, the performance of the memory system can be improved or enhanced.

FIG. 5 illustrates a configuration of a volatile memory device included in a memory controller according to an embodiment of the present disclosure.

Referring to FIG. 5, in addition to the request buffer 232 and the response buffer 234 described in FIG. 4, a plurality of buffers may be set in the volatile memory 216.

According to an embodiment, the volatile memory 216 can include a status information buffer 240. For example, the memory management circuit 162 can store operation information regarding the memory controller or the memory device in the status information buffer 240. Other components can determine whether to perform a service, task, or operation based on a value stored in the status information buffer 240.

According to an embodiment, the volatile memory 216 can include a write data buffer 242 and a read data buffer 244. The write data buffer 242 can temporarily store data to be stored in the memory device 180. The read data buffer 244 can temporarily store data output from the memory device 180. According to an embodiment, the write data buffer 242 and the read data buffer 244 can be combined or included in the request buffer 232 and the response buffer 234.

According to an embodiment, the volatile memory 216 can include an error correction code operation (ECC) buffer 246. When there may be an error in data output from the memory device 180, the memory controller can find and correct the error in the data. The error correction code operation can include a plurality of logical operations. The error correction code operation buffer 246 can be used to perform the plurality of logical operations and store operation results of the plurality of logical operations.

According to an embodiment, the volatile memory 216 can include a fault address buffer 236. When an address of a memory cell that has a permanent or temporary fault among the memory cells included in the memory device 180 is stored in the fault address buffer 236, the memory controller can perform the post package repair (PPR) operation regarding the address stored in the fault address buffer 236.

According to an embodiment, the volatile memory 216 can include a post package repair (PPR) buffer 238. The post package repair (PPR) buffer 238 can be used to temporarily store data corresponding to an address of a memory cell where a defect has occurred during a post package repair (PPR) operation before the data would be stored in a memory cell corresponding to a replacement address.

According to an embodiment, the volatile memory 216 can further include other buffers (BUFFER1, BUFFER2) 248, 250 for various purposes.

According to an embodiment, the memory controller can set plural buffers set in the volatile memory 216 whenever necessary. The memory controller can remove a buffer by releasing or canceling buffer setting when a corresponding operation is terminated. In this case, the use of the volatile memory 216 can be very efficient, but overheads can occur from repeatedly setting and releasing the buffer. In addition, according to an embodiment, when the memory controller has set all buffers in the volatile memory 216 and preoccupied a storage area of the volatile memory 216 for the buffers, the use of the volatile memory 216 could be inefficient due to a buffer which is not frequently used or accessed. Accordingly, performance of the memory system could be optimized based on how much of the limited data storage capacity of the volatile memory 216 is allocated to each of the plural buffers.

According to the embodiment, the number of buffers that need to be set in the volatile memory 216 could be reduced. For example, the post package repair (PPR) buffer 238 might be unnecessary while the post package repair (PPR) operation is not performed. In addition, the post package repair (PPR) operation is performed very infrequently, as compared to the data input/output operation. In order to efficiently utilize internal resources, the memory system can have a structure of the volatile memory 216 without the post package repair (PPR) buffer 238 and allocate some space, corresponding to the post package repair (PPR) buffer 238, for other buffers such as the request buffer 232 and the response buffer 234 which could be used for the data input/output operation.

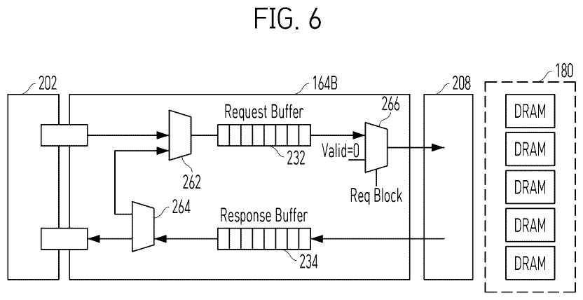

FIG. 6 illustrates a second memory controller according to an embodiment of the present disclosure. For convenience, the memory controllers described in FIG. 4 and FIG. 6 are compared and described with a focus on differences.

Referring to FIG. 4 to FIG. 6, the memory device 180 can include a plurality of DRAMs. The memory interface layer 208 can transfer requests, write data, etc. to the plurality of DRAMs in the memory device 180 or receive read data, etc. from the plurality of DRAMs. The host interface layer 202 can support data communication between an external device (e.g., a host) and the memory controller.

When performing a data input/output operation in the memory system, an input path and an output path may be formed in the host interface layer 202, a data input/output circuit 164B, and the memory interface layer 208.

An address corresponding to a location regarding a defective cell in the memory device 180 can be stored in the defective address buffer 236. To replace a memory cell accessed through an address stored in the defective address buffer 236 with another memory cell (e.g., a redundancy cell), the memory system can perform the post package repair (PPR) operation.

The memory controller can use the input path and the output path used in the data input/output operation while performing the post package repair (PPR) operation. This can eliminate the need to set up the post package repair (PPR) buffer 238 in the volatile memory 216.

For example, because the soft post package repair (sPPR) operation could be often performed to repair a defective cell or row during a current boot cycle of the memory system without a request from the host, it is highly likely that data requested to be stored by the host is stored in the memory cell that is the target of the soft post package repair (sPPR) operation in the memory device 180. Particularly, when an error is found in the data read from the corresponding memory cell via an error detection and correction based on an error detection code or a parity, the memory controller can determine or check whether to perform the soft post package repair (sPPR) operation for an address of the corresponding memory cell. Therefore, if the post package repair (PPR) buffer 238 in the volatile memory 216 is not set, an additional means might be required to move or migrate the read and corrected data stored in the corresponding memory cell to another memory cell designated to replace the corresponding memory cell.

During the post package repair (PRR) operation, if data is stored in a memory cell accessed through the address stored in the defective address buffer 236, the data can be read and then stored in another memory cell to be replaced. Although the post package repair (PPR) buffer 238 in the volatile memory 216 is not set or established, the post package repair (PRR) operation can be understood as a process including a sequentially performed read operation and write operation because the PPR operation includes operations of reading data from the memory device 180 and then storing the read data back in the memory device 180. Accordingly, the data input/output circuit 164B is configured so that the output path can be selectively coupled to the input path for activating a loopback for converting read data into write data.

The data input/output circuit 164B can include a request buffer 232 configured to store a data input/output request on the input path and a response buffer 234 configured to store a response on the output path. According to an embodiment, the data input/output circuit 164B can include a first multiplexer 264, configured to transfer the output of the response buffer 234 to an external device or loopback the output of the response buffer 234 to the request buffer 232, and a second multiplexer 262 configured to transfer one of the output of the first multiplexer 264 and the data input/output request input from the external device to the request buffer 232.

Further, the data input/output circuit 164B can include a third multiplexer 266 configured to selectively transfer the output of the request buffer 232 to the memory device 180. According to an embodiment, the third multiplexer 266 can transfer the output of the request buffer 232 to the memory interface layer 208 or transfer a meaningless signal (e.g., a signal having a value of ‘0’) to the memory interface layer 208 in response to a request blocking signal (Req Block). For example, the request blocking signal (Req Block) can be activated by an operating state of the memory device 180 or an interrupt signal generated within the memory system.

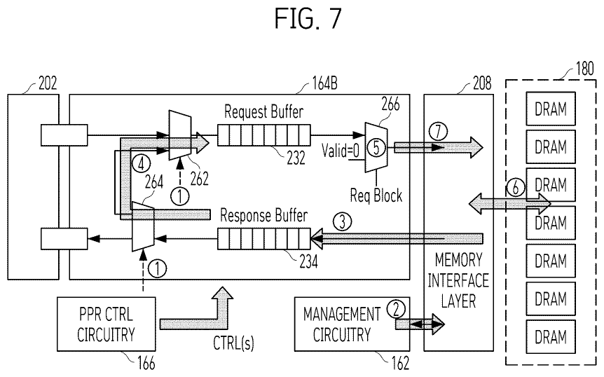

Hereinafter, a method for performing the post package repair (PPR) operation through the data input/output circuit 164B described in FIG. 6 is described. FIG. 7 illustrates the post package repair (PPR) operation of the memory controller described in FIG. 6.

According to an embodiment, the post package repair (PPR) operation regarding a defective or erroneous problematic memory cell in the memory device 180 can be performed while a data input/output operation is not performed through the data input/output circuit 164B. For example, if the post package repair (PPR) operation is performed while the data input/output operation is performed through the data input/output circuit 164B, the data input/output performance of the memory system could deteriorate.

When the post package repair (PPR) operation is performed based on the request input from an external device or an operating situation or status in the memory system, the data input/output circuit (164B) can selectively perform one of the data input/output operation and the post package repair (PPR) operation.

Referring to FIG. 7, in order to perform the post package repair (PPR) operation, a post package repair (PPR) control circuit 166 can control the data input/output circuit 164B. The post package repair control circuit 166 can transfer at least one control signal CTRL(s) to the data input/output circuit 164B.

First, when the post package repair (PPR) operation starts, the post package repair control circuit 166 can transfer a control signal to the first multiplexer 264 and the second multiplexer 262 (\textcircled{1}). The first multiplexer 264 can be set to transfer an output from the response buffer 234 to the second multiplexer 262 by activating the loopback, not transferring the output from the response buffer 234 to the host interface layer 202 for transferring the output from the response buffer 234 to an external device (\textcircled{1}). In addition, the second multiplexer 262 can be set to transfer what is output from the first multiplexer 264 to the request buffer 232, instead of transferring a request input from the external device through the host interface layer 202 to the request buffer 232 (\textcircled{1}).

The memory management circuit 162 can transfer a request to read data stored in a defective or erroneous memory cell that is subject to the post package repair (PPR) operation to the memory interface layer 208 (\textcircled{2}). The memory interface layer 208 can transfer the request to the memory device 180 and transfer data read and output from the memory device 180 to the response buffer 234 (\textcircled{3}).

During the post package repair (PPR) operation, the data stored into the response buffer 234 could be transferred to the request buffer 232 through the first multiplexer 264 and the second multiplexer 262 (\textcircled{4}).

The third multiplexer 266 can block data input to the request buffer 232 from being transferred to the memory interface layer 208 (\textcircled{5}). Data read during the post package repair (PPR) operation should be stored in another memory cell other than the defective or erroneous memory cell in which the data was originally stored. Therefore, the data could be stored in the request buffer 232 until a replacement memory cell is determined.

The post package repair control circuit 166 can perform an operation to select or determine which memory cell can replace the defective or erroneous memory cell through the memory interface layer 208 (\textcircled{5}). For example, the memory interface layer 208 can search for available redundancy cells in the memory device 180 and check an operating status of the searched redundancy cells. In addition, the address (e.g., a row or column address) of the defective or erroneous memory cell could be mapped to an address (e.g., a row or column address) of the redundancy cell to be replaced.

Thereafter, the data stored to the request buffer 232 can be transferred to the memory interface layer 208 through the third multiplexer 266 (\textcircled{7}). The memory interface layer 208 can store the data in a memory cell at a replaced location (e.g., a redundancy cell replacing the defective or erroneous memory cell) based on address mapped information.

As described above, in the memory system, the post package repair (PPR) operation can be performed through the data input/output circuit 164B that is designed and configured to perform the data input/output operation, so that the memory system does not have to set or establish the post package repair (PPR) buffer 238 in the volatile memory 216. Through this scheme, a storage space which could be allocated for the post package repair (PPR) buffer 238 in the volatile memory 216 can be available and used for another buffer set or established for another operation (e.g., the request buffer 232 or the response buffer 234). In this case, the data input/output performance of the memory system could be improved.

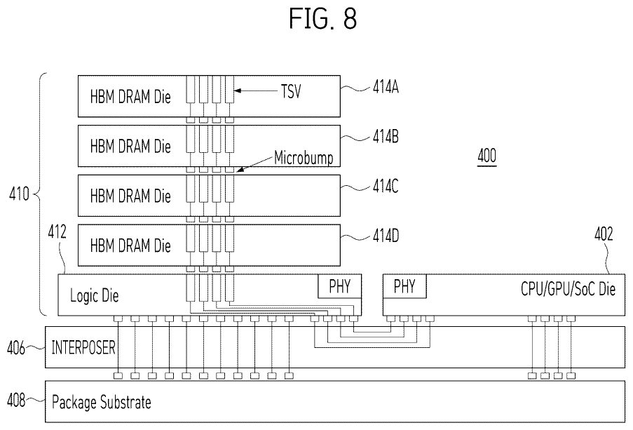

FIG. 8 illustrates a second data processing apparatus 400 according to an embodiment of the present disclosure.

Referring to FIG. 8, the second data processing apparatus 400 can be implemented in the form of a multi-chip package including a plurality of semiconductor devices or a plurality of semiconductor chips. According to an embodiment, the second data processing apparatus 400 can include a high bandwidth memory (HBM) module 410. The HBM module 410 can correspond to the memory system 150 described in FIG. 1.

The second data processing apparatus 400 can include an interposer 406 disposed on a package substrate 408. The interposer 406 can provide a path for data communication between a plurality of devices or a plurality of components. The interposer 406 can be used to simplify the manufacturing process of a multi-chip package for supporting high-speed data communication and to improve signal quality in high-speed data communication. The HBM module 410 disposed on the interposer 406 can include a plurality of memory dies 414A to 414D and a logic die 412. The HBM module 410 described in FIG. 8 can include four memory dies 414A to 414D, but the number of memory dies can be 8, 12, 16, or etc., depending on required performance included in the HBM module 410. According to an embodiment, each of the memory dies 414A to 414D can include a data storage area including volatile memory cells (e.g., DRAM, SRAM, or etc.). According to an embodiment, the plurality of memory dies 414A to 414D can include a data storage area including memory cells of different types (e.g., volatile memory cells and non-volatile memory cells). For example, some of the plurality of memory dies 414A to 414D can be a DRAM memory die, and others may be a NAND memory die.

The plurality of memory dies 414A to 414D can be vertically stacked and can correspond to the memory device 180 described in FIG. 1. The plurality of memory dies 414A to 414D can transmit and receive data or signals through Through-Silicon Vias (TSVs) for vertical electrical connection between the memory dies. In addition, each of the plurality of memory dies 414A to 414D can include a micro bump to maintain a gap with the adjacent die and ensure electrical contact.

A host 402 connected to the HBM module 410 and configured to process data can be placed on the interposer 406. The host 402 can include a central processing unit (CPU), a graphics processing unit (GPU), or a System-on-a-Chip (SoC). The host 402 can correspond to the external device (e.g., the host 110 coupled to the memory system 150 described in FIG. 1). According to an embodiment, the HBM module 410 can be directly connected to the host 402, such as a CPU or a GPU, and can increase bandwidth to bypass the memory controller. This structure might reduce data transmission delay time and improve system performance. For example, the host 402, such as a CPU or a GPU, can send a data read/write request to the HBM module 410, and the HBM controller included in the logic die 412 can analyze a request input from the host 402 and transmit the request to a specific memory bank included in the plurality of memory dies 414A to 414D. The specific memory bank included in the plurality of memory dies 414A to 414D can read or write data requested through the TSV and transmit read data to the host 402, such as a CPU or a GPU, through the interposer 406. In addition, the host 402, such as a CPU or GPU, can process data output from the HBM module 410 and return a result (e.g., data) to the HBM module 410.

According to the embodiment, the HBM controller included in the logic die 412 can include the memory controller 160 described in FIG. 1. The HBM controller included in the logic die 412 can efficiently control the memory banks included in the plurality of memory dies 414A to 414D and manage data transfer based on the priorities assigned to the plurality of data input/output requests.

Further, each of the logic die 412 and the host 402 can include at least one component corresponding to a physical layer PHY which is responsible for transmitting and receiving data or signals therebetween.

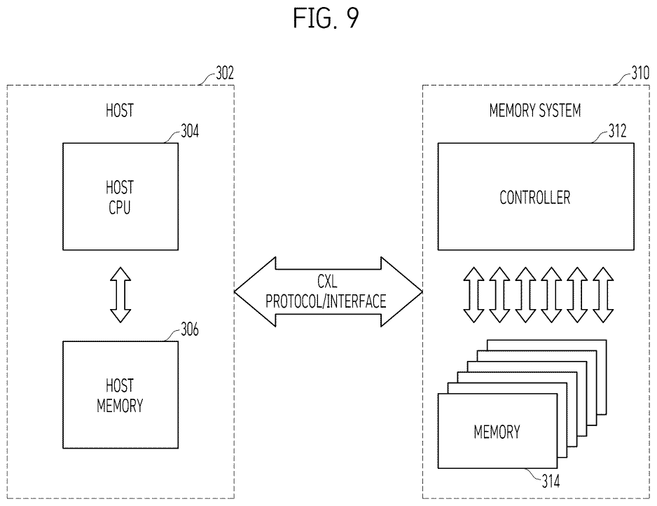

FIG. 9 illustrates a third data processing apparatus according to an embodiment of the present disclosure.

Referring to FIG. 9, the third data processing apparatus may include a host 302 and a memory system 310 (e.g., a compute express link-based (CXL-based) device). The host 302 and the memory system 310 can perform data communication via a computer-memory link-based (e.g., CXL-based) protocol or interface. A controller 312 within the memory system 310 can include the memory controller 160 described in FIG. 1. The controller 312 can manage and control data I/O operations performed in a memory device (or a CXL-based memory device) 314 based on priorities assigned to plural data I/O requests.

The memory system 310 can be designed to support memory-centric computing technology. The memory-centric computing technology can provide a dynamically scalable shared memory that overcomes the limitations of large-capacity data processing performance and capacity occurring in one type of CPU-centric systems that have been proposed, in line with demands or requirements for a memory disaggregation system. Thus, the system scale can be flexibly maintained in line with requirements regarding the data processing apparatus. Due to the explosive increase in amounts of data from emerging applications such as big data and artificial intelligence (AI), the third data processing apparatus including at least one computing device can be designed or built to satisfy large-capacity, high-bandwidth memory, or innovative architectural changes. The number of servers and memory devices can continue to increase to meet overwhelming memory requirements. The computer-memory link-based protocol or computer-memory link-based interface can be provided to support large-capacity and high-bandwidth memory.

Memory disaggregation can be an architectural solution that separates a memory (e.g., a memory device) from a compute node (e.g., a computing device), allowing a system designer to flexibly expand additional memory capacity independently of each computing server while meeting the memory requirements of user applications. For example, a computing server with high memory usage can use a memory device located farther away from other nodes included in a disaggregated group. Accordingly, this disaggregation scheme can manage or use resources more efficiently than one type of dedicated CPU and memory architectures that have been proposed.

The computer-memory link (e.g., Compute Express Link, CXL™) can be provided to accelerate architectural transition to memory disaggregation. The computer-memory link is an industry-supported cache-coherent interconnect (CCI) for various processors to efficiently expand memory capacity through a memory semantic protocol. Unlike a host memory 306 that is entirely dependent on a host central processing unit (CPU) 304, a memory device 314 connected via the CXL-based protocol or CXL-based interface to the host 302 can include additional data or values such as data processing engines through handshaking communication, as a memory.

The host 302 can include the host CPU 304 and the host memory 306. The numbers and configurations of the host CPU 304 and the host memory 306 can vary depending on the performance, operating requirements, operating speed, and data I/O speed of the host 302. The host CPU 304 and the host memory 306 can transmit and receive data through a communication interface protocol mutually agreed upon with each other. There are various communication standards or interfaces such as Universal Serial Bus (USB), Multi-Media Card (MMC), Parallel Advanced Technology Attachment (PATA), Small Computer System Interface (SCSI), Enhanced Small Disk Interface (ESDI), Integrated Drive Electronics (IDE), Peripheral Component Interconnect Express (PCIe), Serial-attached SCSI (SAS), Serial Advanced Technology Attachment (SATA), and Mobile Industry Processor Interface (MIPI), as examples of agreed upon standards for transmitting and receiving data. According to an embodiment, the host 302 and the host memory 306 can be coupled via a Universal Serial Bus (USB). The Universal Serial Bus (USB) can include an expandable, hot-pluggable plug-and-play serial interface that ensures an economical standard connection to peripheral devices such as a keyboard, mouse, joystick, printer, scanner, storage device, modem, video conferencing camera, etc.

In FIG. 9, the host 302 can perform data communication with the memory system 310 through the computer-memory link-based protocol or interface (e.g., CXL-based protocol or CXL-based interface). CXL™ (Compute Express Link) and PCIe (Peripheral Component Interconnect Express) are both standard interfaces for connecting peripherals and CPUs in a computer system. However, there are differences in several aspects between the CXL™ and the PCIe. First, the PCIe is designed as a standard for general input/output devices, while the CXL™ is an interface specialized for memory access and high-speed data transmission in a high-performance computing environment. Thus, the CXL™ is designed so that the CPU can directly access the memory of the device, while the PCIe may have limited such functions. In addition, while the PCIe uses a unidirectional communication way, the CXL™ can support bidirectional communication. For example, the CXL-based devices can support sending and receiving data simultaneously. Because the CXL™ is designed to maintain backward compatibility with the PCIe, the CXL-based device could be designed or implemented by utilizing one type of PCIe infrastructure that has been proposed.

According to an embodiment, data communication of the memory device 314 (e.g., a CXL-based memory device) distributed to the host central processing unit (e.g. CPU) 304 may have a limited interface bandwidth, as compared to that of the host memory 306. For example, in cases of DDR4 DIMM and DDR5 DIMM used as the host memory 306, the DIMM has 64-bit (i.e., 8-byte) data width. The maximum bandwidth could be 2.56 GB/s (=3.2 Gbps×8 bytes) for DDR4 and 38.4 GB/s (=4.8 Gbps×8 bytes) or 51.2 GB/s (=6.4 Gbps×8 bytes) for DDR5. Accordingly, the interface bandwidth may be 0.4 s⁻¹ (=25.6 GB/s /64 GB) and 0.6^{s-1} (=38.4 GB/s /64 GB) or 0.8^{s-1} (=51.2 GB/s/64 GB) when a storage capacity of each chip is 64 Gb. On the other hand, the interface bandwidth of the memory system 310 may be very limited to 0.0625^{s-1} (=32 GB/s(@PCIe5.0×8)/512 GB). This bandwidth difference can limit the input/output performance of the data processing apparatus.

To overcome above-described issues, the memory system 310 may include a controller 312 (e.g., a CXL-based core) designed and used for near data processing (NDP) (or near-distance data processing). The near data processing (NDP) can be a computing scheme for improving or enhancing the efficiency of data processing. The near data processing (NDP) could be based on a configuration in which the controller 312 (e.g., at least one processor or core that processes data) is arranged or located close to a data storage or memory such as the memory device 314.

In one type of computing model that has been proposed, the host CPU 304 would retrieve data from the memory device 314 coupled to expand the host memory 306, process the data, and store results back in the memory device 314. However, in applications that require processing a large amount of data, that scheme could cause a bandwidth bottleneck between the memory device 314 and the host CPU 304. To solve this issue, the near data processing (NDP) can be designed to place the controller 312 (e.g., a processor that processes data) close to the memory device 314 in which the processed data is stored. That is, instead of moving data from the memory device 314 to the host CPU 304, the controller 312, which is the processor that performs data processing, can be included in the memory system 310 which is the location of the data. This configuration can significantly reduce or avoid delay time and energy consumption due to data movement.

Unlike the memory system 310, the host memory 306 can be used for in-memory processing of the host CPU 304. In-memory processing can store as much data as possible in the host memory 306 and reduce the delay time due to disk I/O (e.g., I/O of the memory system). The host memory 306 under this scheme could support great performance in database work, real-time analysis, etc. However, because the host memory 306 is expensive and has limited capacity, there may be limitations in processing very large data sets. Thus, the third data processing apparatus can overcome some limitations of operation and performance of the host memory 306 through the memory system 310 including the controller 312 for the near data processing (NDP).

As above described, a memory system according to an embodiment of the present disclosure can improve data input/output (I/O) performance by efficiently allocating or using internal resources and increasing a utilization rate of limited internal resources.

In addition, a memory system according to an embodiment of the present disclosure can reduce overheads on a storage capacity of volatile memory included in a memory system, because there is no need to set or establish a buffer exclusively used for a post package repair (PPR).

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods or operations of the computer, processor, controller, or other signal processing device, are described in detail, the code or instructions for implementing the operations of the method embodiments may transform the computer, processor, controller, or other signal processing device into a special-purpose processor for performing the methods herein.

Also, another embodiment may include a computer-readable medium, e.g., a non-transitory computer-readable medium, for storing the code or instructions described above. The computer-readable medium may be a volatile or non-volatile memory or other storage device, which may be removably or fixedly coupled to the computer, processor, controller, or other signal processing device which is to execute the code or instructions for performing the method embodiments or operations of the apparatus embodiments herein.

The controllers, processors, control circuitry, devices, modules, units, multiplexers, generators, logic, interfaces, decoders, drivers, and other signal generating and signal processing features of the embodiments disclosed herein may be implemented, for example, in non-transitory logic that may include hardware, software, or both. When implemented at least partially in hardware, the controllers, processors, control circuitry, devices, modules, units, multiplexers, generators, logic, interfaces, decoders, drivers, and other signal generating and signal processing features may be, for example, any of a variety of integrated circuits including but not limited to an application-specific integrated circuit, a field-programmable gate array, a combination of logic gates, a system-on-chip, a microprocessor, or another type of processing or control circuit.

When implemented at least partially in software, the controllers, processors, control circuitry, devices, modules, units, multiplexers, generators, logic, interfaces, decoders, drivers, and other signal generating and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods or operations of the computer, processor, microprocessor, controller, or other signal processing device, are described in detail, the code or instructions for implementing the operations of the method embodiments may transform the computer, processor, controller, or other signal processing device into a special-purpose processor for performing the methods described herein.

While the embodiments of the present disclosure have been illustrated and described with respect to the specific embodiments, it will be apparent to those skilled in the art in light of the present disclosure that various changes and modifications may be made without departing from the spirit and scope of the present disclosure as defined in the following claims. Furthermore, the embodiments may be combined to form additional embodiments.

What is claimed is:

1. A memory system comprising:
at least one memory device; and
a controller comprising an input path for transferring a data input/output (I/O) request input from an external device to the at least one memory device and an output path for transferring a response corresponding to the data I/O request,
wherein the controller is configured to selectively couple the output path to the input path for a post package repair (PPR) operation.

2. The memory system according to claim 1, wherein the controller further comprises:
a request buffer included in the input path and configured to store the data I/O request;
a response buffer included in the output path and configured to store the response;
a first multiplexer configured to transfer an output of the response buffer to the external device or activate a loopback for routing the output of the response buffer to the request buffer; and
a second multiplexer configured to transfer one of the data I/O request and an output of the first multiplexer to the request buffer.

3. The memory system according to claim 2, wherein the controller further comprises a layered structure including:
a first interface layer configured to perform data communication with the external device;
a second interface layer configured to perform data communication with the at least one memory device; and
a control logic layer arranged between the first interface layer and the second interface layer and configured to control or manage operations to be performed through the first interface layer and the second interface layer.

4. The memory system according to claim 3, wherein the control logic layer comprises:
a data input/output circuitry configured to handle or process the data input/output request;
a post package repair control circuitry configured to perform the PPR operation; and
a memory management circuitry configured to check, track, or manage an operation status of the memory system.

5. The memory system according to claim 4, wherein the post package repair control circuitry is configured to:
determine whether to perform the post package repair operation in an idle state; and
control the first multiplexer to loop back the output of the response buffer to the second multiplexer and control the second multiplexer to transfer the output of the first multiplexer to the request buffer to enable the PPR operation.

6. The memory system according to claim 4, wherein the memory management circuitry is configured to:
check whether the memory system is in an idle state to transfer a status of the memory system to the post package repair control circuitry; and
transfer, for the PPR operation, a read request regarding data stored at a first location, which needs to be repaired, to the at least one memory device.

7. The memory system according to claim 6, wherein the controller is configured to:
store the data in a second location, which is different from the first location, in the at least one memory device; and
replace an address of the first location with an address of the second location.

8. The memory system according to claim 3, wherein the controller further comprises a volatile memory configured to store input/output results of tasks processed or transferred in the first interface layer, the second interface layer, and the control logic layer, and
wherein each of the request buffer and the response buffer are set in the volatile memory.

9. The memory system according to claim 3, wherein the controller further comprises a third multiplexer configured to transfer one of the output of the request buffer and a meaningless signal to the at least one memory device.

10. The memory system according to claim 1, wherein the controller is configured to perform an error correction operation on data output from the at least one memory device based on a read request generated by, or transmitted from, a memory management circuitry, and
wherein the controller is configured without a dedicated buffer used for the PPR operation only.

11. A controller comprising:
at least one processor and
at least one memory,
wherein the controller is configured to perform a post package repair (PPR) operation for at least one memory device and activate a loopback for coupling an output path to an input path during the PPR operation, and
wherein the input path is configured to transfer a data input/output (I/O) request input from an external device to the at least one memory device, and the output path is configured to transfer a response corresponding to the data I/O request to the external device.

12. The controller according to claim 11, further comprising:
a request buffer included in the input path and configured to store the data I/O request;
a response buffer included in the output path and configured to store the response;
a first multiplexer configured to transfer an output of the response buffer to the external device or activate a loopback for routing the output of the response buffer to the request buffer; and
a second multiplexer configured to transfer one of the data I/O request and an output of the first multiplexer to the request buffer.

13. The controller according to claim 12, further comprising a layered structure including:
a first interface layer configured to perform data communication with the external device;
a second interface layer configured to perform data communication with the at least one memory device; and
a control logic layer arranged between the first interface layer and the second interface layer and configured to control operations to be performed through the first interface layer and the second interface layer.

14. The controller according to claim 13, wherein the control logic layer comprises:
a data input/output circuitry configured to handle or process the data input/output request;
a post package repair control circuitry configured to perform the PPR operation; and
a memory management circuitry configured to check, track, or manage operation statuses of the at least one memory and the at least one processor.

15. The controller according to claim 14, wherein the post package repair control circuitry is configured to:
determine whether to perform the post package repair operation in an idle state; and
control the first multiplexer to loop back the output of the response buffer to the second multiplexer and control the second multiplexer to transfer the output of the first multiplexer to the request buffer to enable the PPR operation.

16. The controller according to claim 14, wherein the memory management circuitry is configured to:
check whether the data input/output request is input from the external device to transfer a checked status to the post package repair control circuitry; and
transfer, for the PPR operation, a read request regarding data stored at a first location, which needs to be repaired, to the at least one memory device.

17. The controller according to claim 13, further comprising a volatile memory configured to store input/output results of tasks processed or transferred in the first interface layer, the second interface layer, and the control logic layer, and
wherein each of the request buffer and the response buffer are set in the volatile memory.

18. The controller according to claim 13, further comprising a third multiplexer configured to transfer one of the output of the request buffer and a meaningless signal to the at least one memory device.

19. A method for operating a memory system, the method comprising activating a loopback for coupling an output path to an input path during a post package repair (PPR) operation for at least one memory device included in the memory system,
wherein the input path is configured to transfer a data input/output (I/O) request input from an external device to the at least one memory device, and the output path is configured to transfer a response corresponding to the data I/O request to the external device.

20. The method according to claim 19, further comprising:
checking whether the at least one memory device is in an idle state;
performing a read operation regarding data stored at a first location of the at least one memory device, the first location subject to the PPR operation;
storing the data returned through the output path and the input path in a second location of the at least one memory device; and
replacing an address of the first location with an address of the second location.
